(19) United States
(12) Patent Application Publication
(10) Pub. No.: US 2004/0222509 A1
(43) Pub. Date: Nov. 11, 2004

(54) Semiconductor device, electronic device, electronic equipment and manufacturing method thereof

(75) Inventor: Yoshiharu Ogata, Sakata-shi (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/805,179

(22) Filed: Mar. 19, 2004

(30) Foreign Application Priority Data
Mar. 27, 2003 (JP) 2003-088829

(51) Int. Cl. H01L 23/495

(52) U.S. Cl. 257/686

(57) ABSTRACT

A semiconductor device includes a substrate having a terminal to connect a conductive wire, a first semiconductor chip mounted face-up above the substrate and electrically connected to the terminal formed on the substrate by the conductive wire, a second semiconductor chip mounted above the first semiconductor chip via an insulating spacer and a solid material contained in the insulating spacer to keep a distance between the first semiconductor chip and the second semiconductor chip.

### BACKGROUND OF THE INVENTION

1. Field of the Invention

The present invention relates to a semiconductor device, an electronic device, electronic equipment and a manufacturing method thereof and particularly to the stacked structure of a semiconductor chip.

2. Description of the Related Art

According to a conventional semiconductor device, it is necessary to wire-bond stacked semiconductor chips so as to realize a three-dimensional package structure. FIG. 6 is a sectional view showing an outline of a conventional semiconductor device.

In FIG. 6, a land 42 is used to connect a conductive wire 44d and a conductive wire 45d formed on the surface of a carrier substrate 41. A projection electrode 43 is also formed on the back surface of the carrier substrate 41. Moreover, an electronic pad 44b is formed on a semiconductor chip 44a to connect a conductive wire 44d, and an electronic pad 45b is also formed on a semiconductor chip 45a to connect a conductive wire 45d. The semiconductor chip 44a is mounted face-up above the carrier substrate via an adhesive layer 44c. Furthermore, the semiconductor chip 45a is mounted face-up above the semiconductor chip 44a via a mirror chip 46a, sandwiched between an adhesive layer 46b and an adhesive layer 46c. In this case, the semiconductor chip 44a is mounted between the semiconductor chip 44a and the semiconductor chip 45a, being kept away from the electronic pad 44b formed on the semiconductor chip 44a.

The semiconductor chip 44a mounted above the carrier substrate 41 is electrically connected to the land 42 on the carrier substrate 41 by a conductive wire 44d. The semiconductor chip 44b mounted above the semiconductor chip 44a via the mirror chip 46a is also electrically connected to the land 42 on the carrier substrate 41 by the conductive wire 45d. Both the semiconductor chip 44a connected by the conductive wire 44d and the semiconductor chip 45a connected by the conductive wire 44d are molded by the molding resin 47.

Here, the distance between the semiconductor chip 44a and the semiconductor chip 45a can be increased by forming the mirror chip 46a, which is sandwiched between the semiconductor chip 44a and the semiconductor chip 45a. Thereby, it becomes possible to prevent the conductive wire 44d connected to the semiconductor chip 44a of a lower layer from touching the semiconductor chip 45a of an upper layer. As a result, the semiconductor chip 44a of the lower layer can be connected by wire-bonding, even in the case when the semiconductor chip 44a and the semiconductor chip 45a of the same size are stacked.

However, according to the semiconductor device shown in FIG. 6, it is necessary to form the mirror chip 46a between the semiconductor chip 44a and the semiconductor chip 45a in order to connect the semiconductor chip 44a of the lower layer by wire-bonding. Problems exist such as increasing the number of manufacturing steps and the cost.

An aspect of this invention is to provide a semiconductor device, an electronic device, electronic equipment and a manufacturing method thereof, in which the distance between the stacked semiconductor chips can be increased, without adding additional manufacturing steps.

### SUMMARY OF THE INVENTION

In order to solve the problems mentioned above, a semiconductor device described in an aspect of the present invention includes a substrate having a terminal to connect a conductive wire, a first semiconductor chip which is mounted face-up above the substrate and electrically connected to the terminal formed on the substrate by the conductive wire, a second semiconductor chip which is mounted above the first semiconductor chip via an insulating spacer and a solid material contained in the insulating resin to keep a certain distance between the first semiconductor chip and the second semiconductor chip.

Therefore, it is possible to keep a certain distance between the first semiconductor chip and the second semiconductor chip, by mounting the second semiconductor chip above the first semiconductor chip via the insulating spacer and at the same time, fix the first semiconductor chip and the second semiconductor chip. As a result, it is possible to increase the distance between the first semiconductor chip and the second semiconductor chip. Even when the first semiconductor chip is as small as the second semiconductor chip, the first semiconductor chip can be wire-bonded.

Moreover, a semiconductor device according to an embodiment of the present invention includes a substrate having a terminal to connect a conductive wire, a first semiconductor chip mounted face-up above the substrate and electrically connected to the terminal formed on the substrate by a conductive wire, a second wire chip mounted above the first semiconductor chip and a solid material contained in the insulating resin to keep a certain distance between the first semiconductor chip and the second semiconductor chip.

It becomes possible to keep a certain distance between the first semiconductor chip and the second semiconductor chip by mounting the second semiconductor chip above the first semiconductor chip, on which the insulating layer is formed, and it is also possible to fix the first semiconductor chip and the second semiconductor chip. Thereby, the distance between the first semiconductor chip and the second semiconductor chip can be increased without increasing the number of manufacturing steps. Even when the first semiconductor chip is as small as the second semiconductor chip, the first semiconductor chip can be wire-bonded.

Moreover, a semiconductor device according to an aspect of the present invention includes a substrate having a terminal to connect a conductive wire, a first semiconductor chip which is mounted face-up above the substrate, a first electrode pad formed on the first semiconductor chip, a first conductive wire to connect the first electrode pad and the terminal formed on the substrate electrically and a second wire chip mounted above the first semiconductor chip. The semiconductor device also includes a second electrode pad formed on the second semiconductor chip, a second conductive wire to connect the second electrode pad and the terminal formed on the substrate, an insulating resin formed between the first semiconductor chip and the second semiconductor chip in such a way as wrapping the first conductive wire above the first semiconductor chip, a solid material contained in the insulating resin to keep a distance between the first semiconductor chip and the second semiconductor chip and molding resin to mold the first semiconductor chip, to which the first conductive wire is connected, and the second semiconductor chip, to which the second conductive wire is connected.

Therefore, it is possible to keep a certain distance between the first semiconductor chip and the second semiconductor chip by mounting the second conductive chip above the first conductive chip, on which the insulating resin is formed. It is also possible to fix the first conductive wire above the first semiconductor chip by the insulating resin. Accordingly, when the first semiconductor chip, to which the first conductive wire is mounted, is molded by resin, it is possible to prevent the inject pressure of the mold resin from transforming the conductive wire. As a result, the second semiconductor chip can be mounted above the wire-bonded first semiconductor chip without increasing the number of manufacturing steps and also, unusual contact of the first conductive wire can be prevented.

Furthermore, a semiconductor device according to an aspect of the present invention includes a substrate having a terminal to connect a conductive wire, a first semiconductor chip which is mounted face-up above the substrate, a first electronic pad formed on the first semiconductor chip and a first conductive wire to connect the first electrode pad and the terminal formed on the substrate electrically. The semiconductor device also includes a second semiconductor chip formed above the first semiconductor chip, a second electrode pad formed on the second semiconductor chip, a second conductive wire to connect the second electrode pad and the terminal formed on the substrate electrically, an insulating resin formed between the first semiconductor chip and the second semiconductor chip, in such a way as being at least under the second electrode pad, and a solid material contained in the insulating resin to keep a certain distance between the first semiconductor chip and the second semiconductor chip.

Therefore, it is possible to keep a certain distance between the first semiconductor chip and the second semiconductor chip by mounting the second semiconductor chip above the first semiconductor chip, and it is also possible to support the forming area of the second electrode pad by the insulating resin. When the second conductive wire is formed above the second electrode pad, it is possible to prevent the supersonic waves oscillation from destroying the second semiconductor chip at the time of wire-bonding. As a result, it is possible to mount the second semiconductor chip above the first semiconductor chip without increasing the number of manufacturing steps and also, the stable wire-bonding can be achieved.

A semiconductor device according to the embodiment of the present invention is characterized in that it includes further an insulating layer formed on the entire back surface of the second semiconductor chip.

Thereby, it is possible to prevent the first conductive wire from short-circuiting with the back of the second semiconductor chip. As a result, it is possible to mount the second semiconductor chip above the first semiconductor chip stably.

A semiconductor device according to an embodiment of the present invention is characterized in that the size of the solid material is set corresponding to the distance between the first semiconductor chip and the second semiconductor chip. As a result, it becomes possible to set the distance between the first semiconductor chip and the second semiconductor chip based on the size of the solid material.

A semiconductor device according to an aspect of the present invention includes a substrate having a terminal to connect a conductive wire, a first semiconductor chip mounted face-up above the substrate, a second semiconductor chip mounted above the first semiconductor chip via an adhesive layer and electrically connected to the terminal formed on the substrate by a first conductive wire, a third semiconductor chip mounted above the second semiconductor chip via an insulating layer and electrically connected to the terminal formed on the substrate by a second conductive wire, and a solid material contained in the insulating spacer to keep a certain distance between the second semiconductor chip and the third semiconductor chip.

Therefore, it is possible to keep a certain distance between the second semiconductor chip and the third semiconductor chip by mounting the third semiconductor chip above the second semiconductor chip via the insulating spacer and it is also possible to fix the second semiconductor chip and the third semiconductor chip. Moreover, it is possible to mount the first semiconductor chip sandwiched by the second semiconductor chip and the substrate without adding any height. Therefore, it is possible to mount the third semiconductor chip above the wire-bonded second semiconductor chip without increasing the number of manufacturing steps. As a result, it can be realized to increase the number of stackeds of the semiconductor chip with saving space.

A semiconductor device according to an aspect of the present invention includes a substrate having a terminal to connect a conductive wire, a first semiconductor chip mounted face-up above the substrate, a second semiconductor chip mounted above the first semiconductor chip via a adhesive layer and electrically connected to the terminal formed on the substrate by a first conductive wire, a third semiconductor chip mounted above the second semiconductor chip via an insulating layer and electrically connected to the terminal formed on the substrate by a second conductive wire and a solid material contained in the insulating resin to keep a certain distance between the second semiconductor chip and the third semiconductor chip.

Therefore, it is possible to keep a certain distance between the second semiconductor chip and the third semiconductor chip by mounting the third semiconductor chip above the second semiconductor chip, on which the insulating resin is formed, and it is also possible to fix the second semiconductor chip and the third semiconductor chip. Moreover, it is possible to mount the first semiconductor chip sandwiched by the second semiconductor chip and the substrate without adding any height. Therefore, it is possible to mount the third semiconductor chip above the wire-bonded second semiconductor chip without increasing the number of manufacturing step. As a result, it can be realized to increase the number of stackeds of the semiconductor chip with saving space.

A semiconductor device according to an aspect of the present invention is characterized in that the elasticity of the solid material is better than that of the semiconductor chip. Therefore, it is possible to reduce the stress given to the stacked semiconductor chips, which leads to improve the reliability of a semiconductor device having a semiconductor chip, without increasing the number of manufacturing steps.

A semiconductor device according to an aspect of the present invention is characterized in that the solid material is a globular particle. Therefore, it is possible to set the distance between the semiconductor chips according to the size of the solid material, without depending on the inclination of the solid material itself. So, it is not necessary to form the solid material on the semiconductor chip in a given direction so as to keep a certain distance between the semiconductor chips. Therefore, it becomes possible to keep a certain distance between the semiconductor chips by mounting the semiconductor chip via the insulating resin containing the solid material. As a result, it is possible to realize the stacked structure of the wire-bonded semiconductor chips, without increasing the number of manufacturing steps.

A semiconductor device according to an aspect of the present invention is characterized in that the maximum of the radius of the globular particle is practically equal to the thickness of the insulating spacer or that of the insulating resin. Therefore, it is possible to set the distance between the semiconductor chips depending on the radius of the globular particle. In other words, the distance between the semiconductor chips can be controlled by changing the maximum of the radius of the globular particle. Therefore, it becomes possible to increase the distance between the mounted semiconductor chips without increasing the number of manufacturing steps. Even when the size of the mounted semiconductor chips is equal to each other, it is possible to realize the stacked structure of the wire-bonded semiconductor chip.

A semiconductor device according to an aspect of the present invention is characterized in that the weight of the globular particle is within the range 1% through 10% of the weight of the insulating spacer or that of the insulating resin. Therefore, it is possible to fix the semiconductor chip via the insulating spacer or the insulating resin, with keeping a certain distance between the semiconductor chips.

A semiconductor device according to an aspect of the present invention includes a substrate having a terminal to connect a conductive wire, a first electronic part mounted face-up above the substrate and electrically connected to the terminal formed on the substrate by the conductive wire, a second electronic part mounted above the first electronic part via an insulating spacer and a solid material contained in the insulating resin to keep a certain distance between the first electronic part and the second electronic part.

Therefore, it is possible to keep a certain distance between the first electronic part and the second electronic part by mounting the second electronic part above the first electronic part via the insulating spacer and it is also possible to fix the first electronic part and the second electronic part. Therefore, it becomes possible to increase the distance between the first electronic part and the second electronic part without increasing the number of manufacturing steps. Even when the first electronic part is as small as the second electronic part, the first electronic part can be wire-bonded.

A semiconductor device according to an embodiment of the present includes a substrate having a terminal to connect a conductive wire, a first semiconductor chip mounted face-up above the substrate and electrically connected to the terminal formed on the substrate by the conductive wire, a second semiconductor chip mounted above the first semiconductor chip via an insulating spacer, a solid material contained in the insulating spacer to keep a certain distance between the first semiconductor chip and the second semiconductor chip and an electronic part, which is electrically connected to the first semiconductor chip and the second semiconductor chip via the substrate.

Therefore, it is possible to achieve the stacked structure of the wire-bonded semiconductor chip, without increasing the number of manufacturing steps, which leads to a lower cost of the electronic equipment. Moreover, a manufacturing process of a semiconductor device according to the present invention includes the steps of mounting a first semiconductor chip above a substrate having a terminal to connect a conductive wire, connecting the first semiconductor chip mounted above the substrate and the terminal formed on the substrate by the conductive wire, forming an insulating spacer containing a particle on the first semiconductor chip connected by the conductive wire and mounting a second semiconductor chip above the first semiconductor chip via the insulating spacer.

Therefore, it is possible to prevent the conductive wire from touching the second semiconductor chip by mounting the second semiconductor chip above the first semiconductor chip via the insulating spacer, even when the second semiconductor chip is mounted above the wire-bonded first semiconductor chip. As a result, it is possible to reduce the cost of the stacked structure of the wire-bonded semiconductor chip.

The manufacturing process of the present invention includes the steps of mounting a first semiconductor chip above a substrate having a terminal to connect a conductive wire, connecting a first semiconductor chip mounted above the substrate and the terminal formed on the substrate by the conductive wire, mounting an insulating spacer containing a particle on the first semiconductor chip connected by the conductive wire, and mounting a second semiconductor chip above the first semiconductor chip via the insulating spacer.

Therefore, when the second semiconductor chip is mounted above the first wire-bonded semiconductor chip, it is possible to prevent the conductive wire from touching the second semiconductor chip. As the result, it is possible to reduce the cost of the stacked structure of the wire-bonded semiconductor chip.

### BRIEF DESCRIPTION OF THE DRAWINGS

FIG. 1 is a sectional view showing an outline of the semiconductor device according to a first embodiment of the present invention.

FIG. 2 is a sectional view showing a manufacturing process of the semiconductor device shown in FIG. 1.

FIG. 3 is a sectional view showing an outline of the semiconductor device according to a second embodiment of the present invention.

FIG. 4 is a sectional view showing an outline of the semiconductor device according to a third embodiment of the present invention.

FIG. 5 is a sectional view showing an outline of the semiconductor device according to a fourth embodiment of the present invention.

FIG. 6 is a sectional view showing an outline of a conventional semiconductor device.

### DESCRIPTION OF THE PREFERRED EMBODIMENTS

A preferred embodiment of the present invention and the manufacturing process thereof is described, referring to the figures.

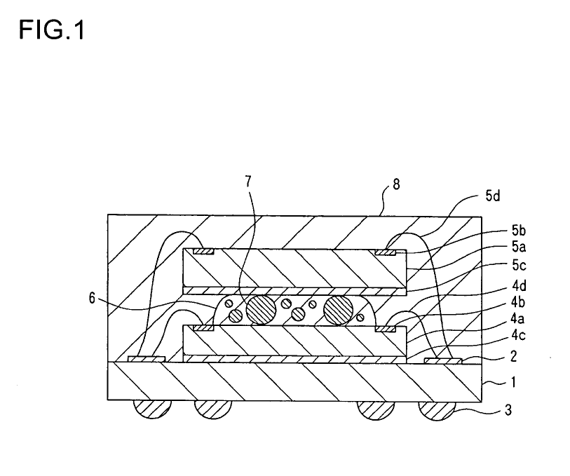

FIG. 1 is a sectional view showing an outline of the first embodiment of a semiconductor device according to the present invention.

As shown in FIG. 1, a land 2 used to connect a conductive wire 4d and a conductive wire 5d is mounted on the surface of a carrier substrate 1. In addition, a projection electrode 3 is mounted on the back surface of the carrier substrate 1. For example, a stacked substrate, a stacked-wiring substrate, a build-up substrate, a tape substrate and a film substrate, and so on can be used for the carrier substrate 1. As for the material of the carrier substrate 1, for example, a polymide resin, a glass-epoxy resin, a BT resin, a composite of aramid and epoxy, and a ceramic, and so on can be used. As for the projection electrode 3, for example, an Au bump, a Cu bump and a Ni bump insulated by the solder material and such, and solder ball and so on can be used.

Moreover, electrode pads 4b,5b are formed on a semiconductor chip 4a and 5a, respectively, to connect conductive wires 4d, 5d, respectively. Then, an insulating layer 5c is formed on the back surface of the semiconductor chip 5a. For example, an Au wire and an AI wire, and so on can be used for the conductive wire 4d and the conductive wire 5d. For example, an insulating sheet and an insulating paste, and so on can be used for the insulating layer. In this case, the insulating layer 5c formed on the back surface of the semiconductor chip 5a can be omitted.

The semiconductor chip 4a is mounted above the carrier substrate face-up via an adhesive layer 4c. In addition, the semiconductor chip 5a is mounted above the semiconductor chip 4a face-up via an insulating resin 6, which contains particles 7. For example, a paste-shape resin or a sheet-shape resin can be used for the insulating resin 6, such as an epoxy-type resin, an acrylic-type resin, and a maleimide-type resin, and so on can be used. The radius of the particle 7 can be set in the range from 30 to 150 μmØ.

The semiconductor chip 4a mounted above the carrier substrate 1 is electrically connected to the land 2 on the carrier substrate 1 by the conductive wire 4d, and the semiconductor chip 5a mounted above the semiconductor chip 4a via the insulating resin 6 is also electrically connected to the land 2 on the carrier substrate 1 by the conductive wire 5d. Both the semiconductor chip 4a, to which the conductive wire 4d is connected, and the semiconductor chip 5a, to which the conductive wire 5d is connected, are molded by the molding resin 8.

The size of the particles 7 contained in the insulating resin 6 can be set so as to prevent the conductive wire 4d from touching the semiconductor chip 5a, and at the same time to keep a certain distance between the semiconductor chip 4a and the semiconductor chip 5a by the particle 7. For example, the size of the particles 7 can be made equal to the thickness of the insulating resin 6 filled between the semiconductor chip 4a and the semiconductor chip 5a.

Thereby, it is possible to keep a certain distance between the semiconductor chip 4a and the semiconductor chip 5a and also fix the semiconductor chip 4a and the semiconductor chip 5a by mounting the semiconductor chip 5a above the semiconductor chip 4a, on which the insulating resin 6 is formed. As a result, it is possible to increase the distance between the semiconductor chip 4a and the semiconductor chip 5a without increasing the number of manufacturing steps. Even when the semiconductor chip 4a is as small as the semiconductor chip 5a, it is possible to mount the semiconductor chip 5a above the semiconductor chip 4a, to which the conductive wire 4d is connected.

In this case, although a different size of the particles can be contained in the insulating resin 6, it is preferable that the maximum size of the particles 7 is practically equal to the thickness of the insulating resin 6. It is also preferable that at least three of the particles 7, whose size is practically equal to the thickness of the insulating resin 6, are contained. Thereby, it is possible to set the distance between the semiconductor chip 4a and the semiconductor chip 5a depending on the size of the particles 7. It becomes possible to control the distance between the semiconductor chip 4a and the semiconductor chip 5a by changing the maximum size of the particles 7.

It is also preferable that the shape of the particles is spherical. Accordingly, it becomes possible to set the distance between the semiconductor chip 4a and the semiconductor chip 5a according to just the size of the particles 7, without depending on the inclination of the particles 7. As a result, it is not necessary to arrange the particles 7 in a given direction on the semiconductor chip 4a, so as to keep a certain distance between the semiconductor chip 4a and the semiconductor chip 5a. In other words, it is possible to keep a certain distance between the semiconductor chip 4a and the semiconductor chip 5a by mounting the semiconductor chip 4a and the semiconductor chip 5a via the insulating resin 6, which contains the particles 7. It is possible to create a stacked structure of the wire-bonded semiconductor chip 4a and the wire-bonded semiconductor chip 5a, without increasing the number of manufacturing steps.

Moreover, it is preferable that the elasticity of the particles 7 is better than that of the semiconductor chip 4a and the semiconductor chip 5a. For example, polystyrene-group resin and acrylic-group resin and so on can be used. It becomes possible to reduce the stress given to the stacked semiconductor chip 4a and the stacked semiconductor chip 5a. As a result, it is realized to improve the reliability of the semiconductor device having the stacked structure of the semiconductor chip 4a and the semiconductor chip 5a, without increasing the number of manufacturing step. It is also preferable that the height of the particle 7 is within the range 1% through 10% of the height of the insulating resin 6.

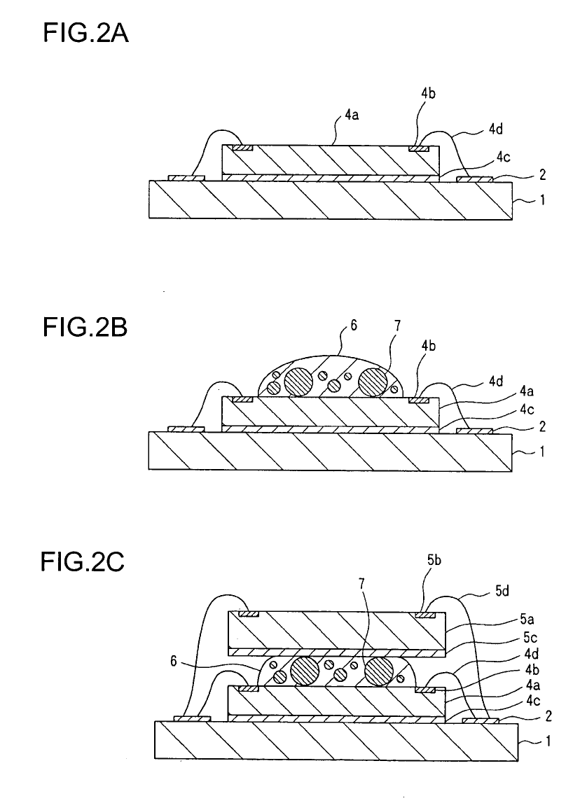

FIG. 2 is a sectional view showing the manufacturing process of the semiconductor device shown in FIG. 1.

As shown in FIG. 2(a), the semiconductor chip 4a is mounted above the carrier substrate 1 face-up via the adhesive layer 4c. The land 2 and the electrode pad 4b are connected by the conductive wire 4d, by wire-bonding the semiconductor chip 4a mounted on the carrier substrate 1 face-up.

Next, as shown in FIG. 2(b), the insulating resin 6 containing the particles 7 is formed on the semiconductor chip 4a, to which the conductive wire 4d is connected. When the insulating resin 6 containing the particles 7 is formed on the semiconductor chip 4a, a dispenser can be used, for example.

Next, as shown in FIG. 2(c), a semiconductor chip 5a, having an insulating layer 5c formed on its back surface, is mounted above the semiconductor chip 4a face-up via the insulating resin 6 containing the particles 7. Then, the semiconductor chip 5a is pressed against the semiconductor chip 4a, and the insulating resin 6 is kept to be pressed until it is impossible to make the distance between the semiconductor chip 4a and the semiconductor chip 5a narrow any more, opposing to the hardness of the particles 7. As a result, it becomes possible to set the distance between the semiconductor chip 4a and the semiconductor chip 5a, depending on the size of the particles 7. As a result, it is realized to mount the semiconductor chip 4a above the semiconductor chip 5a, while preventing the semiconductor chip 5a from touching the conductive wire 4d connected to the semiconductor chip 4a.

Next, the insulating resin 6 is hardened, while keeping a certain distance between the semiconductor chip 4a and the semiconductor chip 5a via the particles 7. Then, the land 2 and the electrode pad 5b are connected by the conductive wire 5d, by wire-bonding the semiconductor chip 5a mounted above the semiconductor chip 4a face-up.

Then, as shown in FIG. 1, the semiconductor chip 4a, to which the conductive wire 4d is connected, and the semiconductor chip 5a, to which the conductive wire 4d is connected, are molded by the molding resin 8, in such a way as a transfer-mold and so on.

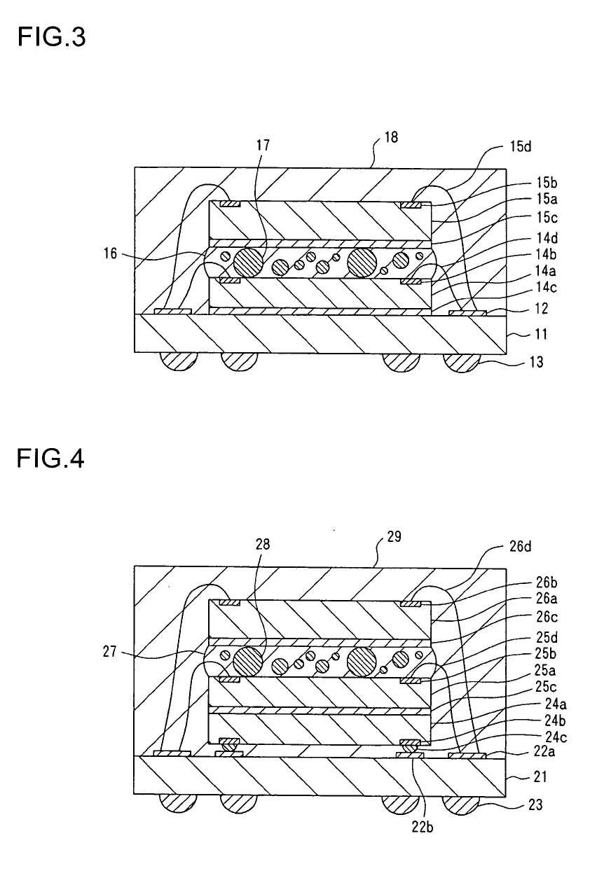

FIG. 3 is a sectional view showing an outline of the second embodiment of the semiconductor device according to the present invention.

As shown in FIG. 3, a land 12 is formed on the surface of a carrier substrate 11 to connect a conductive wire 14d and a conductive wire 15d. A projection electrode 13 is formed on the back surface of the carrier substrate 11. An electrode pad 14b used to connect the conductive wire 14d is formed on a semiconductor chip 14a and an electrode pad 15b to connect the conductive wire 15d is formed on a semiconductor chip 15a. An insulating layer 15c is formed on the back surface of the semiconductor chip 15a. Here, the insulating layer 15c formed on the back surface of the semiconductor chip 15a can be omitted.

Then, the semiconductor chip 14a is mounted above the carrier substrate 11 face-up via an adhesive layer 14c. Moreover, the semiconductor chip 15a is mounted above the semiconductor chip 14a face-up via the insulating resin 16 containing particles 17.

The semiconductor chip 14a is electrically connected to the land 12 on the carrier substrate 11 by the conductive wire 14d, while on the other hand, the conductive chip 15a, which is mounted above the conductive chip 14a via the insulating resin 16, is electrically connected to the land 12 on the carrier substrate 11 by the conductive wire 15d. Then the semiconductor chip 14a, to which the conductive wire 14d is connected, and the semiconductor chip 15a, to which the conductive wire 14d is connected, are molded by the molding resin 18.

In this case, the size of particles 17 contained in the insulating resin 16 is set so as to prevent the conductive wire 14d from touching the semiconductor chip 15a, while keeping a certain distance between the semiconductor chip 14a and semiconductor chip 15a via the particles 17. Moreover, it is possible to fill the insulating resin 16 between the semiconductor chip 14a and semiconductor chip 15a, so as to wrap the conductive wire 14d above the semiconductor chip 14a. Thereby, the conductive wire 14d above the semiconductor chip 14a can be fixed by the insulating resin 16, while keeping a certain distance between the semiconductor chip 14a and the semiconductor chip 15a. Even when the semiconductor chip 14a, to which the conductive wire 14d is connected, is molded by resin, it is possible to prevent the injection pressure of the molding resin 18 from transforming the semiconductor chip 14a. As a result, it is possible to mount the semiconductor chip 15a above the wire-bonded semiconductor chip 14a without increasing the number of manufacturing steps. Also, an unusual touch of the conductive wire 14d can be prevented.

Furthermore, it is possible to fill the insulating resin 16 between the semiconductor chip 14a and the semiconductor chip 15a, in such a way as the insulating resin 16 is even under the electrode pad 15b. Thereby, it becomes possible to support the forming area for the electrode pad 15b by the insulating resin 16, while keeping a certain distance between the semiconductor chip 14a and the semiconductor chip 15a. Even when the conductive wire 15d is connected to the electrode pad 15b, it is possible to prevent the supersonic wave vibrations at the time of wire-bonding from destroying the semiconductor chip 15a. As a result, it is possible to mount the semiconductor chip 15a above the wire-bonded semiconductor chip 14a, without increasing the number of manufacturing steps. Furthermore, a stable wire-bonding can be realized.

FIG. 4 is a sectional view showing an outline of the third embodiment of the semiconductor device according to the present invention.

As shown in FIG. 4, a land 22a used to connect a conductive wire 25d and a conductive wire 26d is formed on the surface of the carrier substrate 21 and also, a land 22b is used to connect a projection electrode 24c. Then, a projection electrode 23 is formed on the back surface of the carrier substrate 21. Moreover, an electrode pad 24b having the projection electrode 24c is formed on a semiconductor chip 24a. Furthermore, an electrode pad 25b to connect a conductive wire 25d is formed on a semiconductor chip 25a and an electrode pad 26b to connect a conductive wire 26d is formed on a semiconductor chip 26a. An insulating layer 26c is formed on the back surface of the semiconductor chip 26a, In this case, an Au bump, a Cu bump and a Ni bump insulated by solder material and so on, and a solder ball and so on are used for the projection electrode 23 and the projection electrode 24c, for example. Here, the insulating layer 26c formed on the back surface of the semiconductor chip 26a can be omitted.

A semiconductor chip 24a is mounted above the carrier substrate 21 in a flip-chip via the projection electrode 24c. In this case, when the semiconductor chip 24a is mounted above the carrier substrate 21 in a flip-chip via the projection electrode 24c, such adhesion bonds as an ACF (Anisotropic Conductive Film) connection, a NCF (Nonconductive Film) connection, and a NCP (Nonconductive Paste) connection, and so on can be used. Also, the metal bonds, such as a solder-bond and an alloy-bond, and so on can be used.

Moreover, a semiconductor chip 25a is mounted face-up above the back surface of the semiconductor chip 24a, which is mounted in a flip-chip via an adhesive layer 25c. A semiconductor chip 26a is also mounted face-up above the semiconductor chip 25a via an insulating resin 27 containing particles 28.

Furthermore, the semiconductor chip 25a, which is mounted on the back surface of the semiconductor chip 24a, is electrically connected to the land 22a on the carrier substrate 21 by the conductive wire 25d. The semiconductor chip 26a, which is died above the semiconductor chip 25a via the insulating resin 27, is also electrically connected to the land 22a on the carrier substrate 21 by the conductive wire 26d. Here, the semiconductor chip 24a mounted in a flip-chip, the semiconductor chip 25a, to which the conductive wire 25d is connected, and the semiconductor chip 26a, to which the conductive wire 26d is connected, are molded by the molding resin 29.

In this case, the size of the particles 28 contained in the insulating resin 27 is set so as to prevent the conductive wire 25d from touching the semiconductor chip 26a, while keeping a certain distance between the semiconductor chip 25a and the semiconductor chip 26a via the particle 28. Moreover, it is possible to fill the insulating resin 27 between the semiconductor chip 25a and semiconductor chip 26a, so as to wrap the conductive wire 25d above the semiconductor chip 25a. It is also possible to fill the insulating resin 27 between the semiconductor chip 25a and the semiconductor chip 26a so that the insulating resin 27 can be under the electrode pad 26b in the semiconductor chip 26a.

Consequently, it becomes possible to fix the semiconductor chip 25a and the semiconductor chip 26a, with keeping a certain distance between the wire-bonded semiconductor chip 25a and the wire-bonded semiconductor chip 26a. It also becomes possible to mount the semiconductor chip 24a sandwiched between the semiconductor chip 25a and the carrier substrate 21 without adding any height. As a result, it is possible to mount the semiconductor chip 26a above the wire-bonded semiconductor chip 25, without increasing the number of manufacturing steps. Thus, it is possible to increase the number of stacks of the semiconductor chips 24a through 26a, with saving space.

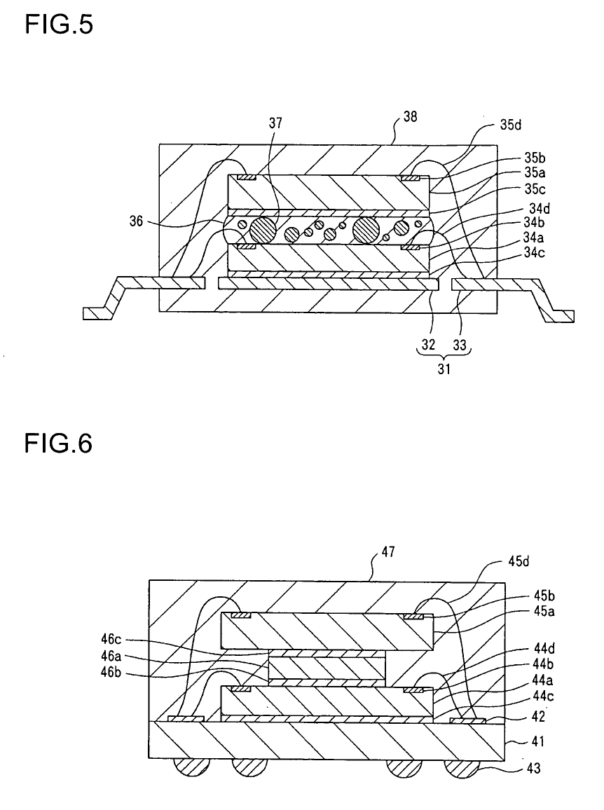

FIG. 5 is a sectional view showing an outline of the fourth embodiment of the semiconductor device according to the present invention.

As shown in FIG. 5, a die-pad 32 to die-bond a semiconductor chip 34a and a lead 33 to connect a conductive wire 34d and a conductive wire 35d are formed on a lead-frame 31. Moreover, an electrode pad 34b to connect a conductive wire 34d is formed on the semiconductor chip 34a, and an electrode pad 35b to connect a conductive wire 35d is formed on the semiconductor chip 35a, respectively. An insulating layer 35c is formed on the back surface of the electrode pad 34b. In this case, the insulating layer 35c formed on the back surface of the semiconductor chip 35a can be omitted.

Then, the semiconductor chip 34a is mounted face-up above the die-pad 32 of the lead-frame 31 via an adhesive layer 34. In addition, the semiconductor chip 35a is mounted face-up above the semiconductor chip 34a via an insulating resin 36 containing particles 37.

Then, the die-bonded semiconductor chip 34a above the die-pad 32 is electrically connected to the lead 33 of the lead-frame 31 by the conductive wire 34d. The semiconductor chip 35a, which is mounted above the semiconductor chip 34a, is electrically connected to the lead 33 of the lead-frame 31 by the conductive wire 35d. Both the semiconductor chip 34a, to which the conductive wire 34d is connected, and the semiconductor chip 35a, to which the conductive wire 35d is connected, are molded by the molding resin 38.

In this case, the size of the particle 37 contained in the insulating layer 36 is set so as to prevent the conductive wire 34d from touching the semiconductor chip 35a, with keeping a certain distance between the semiconductor chip 34a and the semiconductor chip 35a via the particle 37. Moreover, it is possible to fill the insulating resin 36 between the semiconductor chip 34a and semiconductor chip 35a so as to wrap the conductive wire 34d above the semiconductor chip 34a.

Thereby, even when the semiconductor chip 34a and the semiconductor chip 35a are mounted above the lead-frame 31 in a stacked structure, it is possible to mount the semiconductor chip 35a above the semiconductor chip 34a, to which the conductive wire 34d is connected, while keeping a certain distance between the semiconductor chip 34a and the semiconductor chip 35a. As a result, it is possible to reduce the cost of the semiconductor device.

The semiconductor device described above can be applied to electronic equipment, such as a liquid crystal display device, a mobile telephone, a personal digital assistant, a video camera, a digital camera and a MC(Mini Disc)player and so on, for example. It is possible to make electronic equipment smaller and lighter and to reduce its cost.

What is claimed is:

1. A semiconductor device, comprising:
a substrate having a terminal to connect a conductive wire;
a first semiconductor chip mounted face-up above the substrate and electrically connected to the terminal formed on the substrate by the conductive wire;
a second semiconductor chip mounted above the first semiconductor chip via an insulating spacer; and
a solid material contained in the insulating spacer to keep a distance between the first semiconductor chip and the second semiconductor chip.

2. A semiconductor device, comprising:
a substrate having a terminal to connect a conductive wire;
a first semiconductor chip mounted face-up above the substrate and electrically connected to the terminal formed on the substrate by the conductive wire;
a second semiconductor chip mounted above the first semiconductor chip via an insulating resin; and
a solid material contained in the insulating resin to keep a distance between the first semiconductor chip and the second semiconductor chip.

3. A semiconductor device, comprising:
a substrate having a terminal;
a first semiconductor chip mounted face-up above the substrate;
a first electrode pad formed on the first semiconductor chip;
a first conductive wire connecting the first electrode pad and the terminal formed on the substrate electrically;
a second semiconductor chip mounted above the first semiconductor chip;
a second electrode pad formed on the second semiconductor chip;
a second conductive wire connecting the second electrode pad and the terminal formed on the substrate;
an insulating resin formed between the first semiconductor chip and the second semiconductor chip in such a way as wrapping the first conductive wire above first semiconductor chip;
a solid material contained in the insulating resin to keep a distance between the first semiconductor chip and the second semiconductor chip; and
molding resin to mold the first semiconductor chip to which the first conductive wire is connected and the second semiconductor chip to which the second conductive wire is connected.

4. A semiconductor device, comprising:
a substrate having a terminal;
a first semiconductor chip mounted face-up above the substrate;
a first electronic pad formed on the first semiconductor chip;
a first conductive wire connecting the first electrode pad and the terminal formed on the substrate electrically;
a second semiconductor chip mounted above the first semiconductor chip;
a second electrode pad formed on the second semiconductor chip;
a second conductive wire connecting the second electrode pad and the terminal formed on the substrate electrically;
an insulating resin mounted between the first semiconductor chip and the second semiconductor chip and being at least under the second electrode pad; and
a solid material contained in the insulating resin to keep a distance between the first semiconductor chip and the second semiconductor chip.

5. The semiconductor device according to claim 1, further comprising an insulating layer formed entirely on a back portion of the second semiconductor chip.

6. The semiconductor device according to claim 1, wherein a size of the solid material is set corresponding to the distance between the first semiconductor chip and the second semiconductor chip.

7. A semiconductor device, comprising:
a substrate having a terminal;
a first semiconductor chip mounted in a flip-chip above the substrate;
a second semiconductor chip mounted face-up above the first semiconductor chip via an adhesive layer and electrically connected to the terminal by a first conductive wire;
a third semiconductor chip mounted face-up above the second semiconductor chip via an insulating spacer and electrically connected to the terminal by a second conductive wire; and
a solid material contained in the insulating spacer to keep a distance between the second semiconductor chip and the third semiconductor chip.

8. A semiconductor device, comprising:
a substrate having a terminal;
a first semiconductor chip mounted face-up above the substrate;
a second semiconductor chip mounted above the first semiconductor chip via an adhesive layer and electrically connected to the terminal formed on the substrate by a first conductive wire;
a third semiconductor chip mounted face-up above the second semiconductor chip via an insulating layer and electrically connected to the terminal formed on the substrate by a second conductive wire; and
a solid material contained in the insulating resin to keep a distance between the second semiconductor chip and the third semiconductor chip.

9. The semiconductor device according to claim 1, wherein an elasticity ability of the solid material is better than an elasticity ability of the semiconductor chip.

10. The semiconductor device according to claim 1, wherein the solid material is a globular particle.

11. The semiconductor device according to claim 10, wherein a maximum of a radius of the globular particle is practically equal to a thickness of the insulating spacer.

12. The semiconductor device according to claim 10, wherein a weight of the globular particle is within a range from 1% through 10% of that of the insulating spacer.

13. A semiconductor device, comprising:
a substrate having a terminal to connect a conductive wire;
a first electronic part mounted face-up above the substrate and electrically connected to the terminal that is formed on the substrate by the conductive wire;
a second electronic part mounted above the first electronic part via an insulating spacer; and
a solid material contained in the insulating spacer to keep a certain distance between the first electronic part and the second electronic part.

14. An electronic equipment, comprising:
a substrate having a terminal to connect a conductive wire;
a first semiconductor chip mounted face-up above the substrate and
electrically connected to the terminal formed on the substrate by the conductive wire;
a second semiconductor chip mounted above the first semiconductor chip via an insulating spacer;
a solid material contained in the insulating spacer to keep a distance between the first semiconductor chip and the second semiconductor chip; and
an electronic part electrically connected to the first semiconductor chip and the second semiconductor chip via the substrate.

15. A method of manufacturing a semiconductor device, comprising:
mounting a first semiconductor chip above a substrate having a terminal to connect a conductive wire;
connecting the first semiconductor chip mounted above the substrate and the terminal formed on the substrate by the conductive wire;
forming an insulating spacer containing a particle above the first semiconductor chip which is connected by the conductive wire; and
mounting a second semiconductor chip above the first semiconductor chip via the insulating spacer.

16. A method of manufacturing a semiconductor device, comprising:
mounting a first semiconductor chip above a substrate having a terminal to connect a conductive wire;
connecting the first semiconductor chip mounted above the substrate and the terminal formed on the substrate by the conductive wire;
forming an insulating resin containing a particle on the first semiconductor chip, which is connected by the conductive wire; and
mounting a second semiconductor chip above the first semiconductor chip via the insulating resin.

17. The semiconductor device according to claim 2, further comprising an insulating layer formed entirely on a back portion of the second semiconductor chip.

18. The semiconductor device according to claim 3, further comprising an insulating layer formed entirely on a back portion of the second semiconductor chip.

19. The semiconductor device according to claim 4, further comprising an insulating layer formed entirely on a back portion of the second semiconductor chip.

20. The semiconductor device according to claim 2, wherein a size of the solid material is set corresponding to the distance between the first semiconductor chip and the second semiconductor chip.
